(19) United States
(12) Patent Application Publication
(10) Pub. No.: US 2026/0013129 A1
(43) Pub. Date: Jan. 8, 2026

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Yang Bok LEE, Gyeonggi-do (KR); Eun Yi KO, Gyeonggi-do (KR); Sung Soon KIM, Gyeonggi-do (KR); Pan Uk HONG, Gyeonggi-do (KR)

(21) Appl. No.: 18/919,429

(22) Filed: Oct. 18, 2024

(30) Foreign Application Priority Data
Jul. 8, 2024 (KR) 10-2024-0089385

(51) Int. Cl. H10B 43/27; H01L 23/00; H01L 25/065; H01L 25/18; H10B 41/27; H10B 80/00

(52) U.S. Cl. CPC H10B 43/27; H01L 24/08; H01L 25/0657; H01L 25/18; H10B 41/27; H10B 80/00; H01L 2224/08145; H01L 2924/1431; H01L 2924/14511

(57) ABSTRACT

A semiconductor device may include a source structure; a gate structure including conductive layers and insulating layers that are alternately stacked; a first channel layer including a first penetration portion extending through the gate structure and a first tip having a smaller width than the first penetration portion and protruding into the source structure; a second channel layer including a second penetration portion extending through the gate structure and a second tip having a smaller width than the second penetration portion and protruding into the source structure; and a slit structure extending through the gate structure, wherein the first tip and the second tip may have different heights.

### CROSS-REFERENCE TO RELATED APPLICATION

This application claims priority under 35 U.S.C. § 119 to Korean Patent Application No. 10-2024-0089385 filed on Jul. 8, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by the area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods are being developed.

### SUMMARY

In an embodiment of the present disclosure, a semiconductor device may include a source structure; a gate structure including conductive layers and insulating layers that are alternately stacked; a first channel layer including a first penetration portion extending through the gate structure and a first tip having a smaller width than the first penetration portion and protruding into the source structure; a second channel layer including a second penetration portion extending through the gate structure and a second tip having a smaller width than the second penetration portion and protruding into the source structure; and a slit structure extending through the gate structure, wherein the first tip and the second tip may have different heights.

In an embodiment of the present disclosure, a manufacturing method of a semiconductor device may include forming a stack over a substrate, the stack including first material layers and second material layers that are alternately stacked; forming an opening extending into the substrate through the stack; forming a gap-fill pattern at a lower portion of the opening; forming a channel structure in the opening where the gap-fill pattern is formed; removing the substrate so that the channel structure protrudes from a surface of the stack; removing the gap-fill pattern; and forming a source structure connected to the channel structure.

In an embodiment of the present disclosure, a manufacturing method of a semiconductor device may include forming a stack over a substrate, the stack including first material layers and second material layers that are alternately stacked; forming an opening extending into the substrate through the stack; forming a buffer pattern by oxidizing the substrate through the opening; forming a gap-fill pattern in the buffer pattern; forming a channel structure in the opening, the channel structure extending into the buffer pattern; removing the substrate to expose the buffer pattern; removing the buffer pattern to expose the gap-fill pattern; removing the gap-fill pattern; and forming a source structure connected to the channel structure.

These and other features and advantages of the present invention will become better understood from the following detailed description of various embodiments of the present disclosure in conjunction with the accompanying drawings.

### BRIEF DESCRIPTION OF THE DRAWINGS

FIG. 1 is a simplified diagram illustrating the structure of a semiconductor device in accordance with an embodiment of the present disclosure.

FIGS. 2A and 2B are simplified diagrams for describing the structure of a semiconductor device in accordance with an embodiment of the present disclosure.

FIGS. 3A and 3B are simplified diagrams for describing the structure of a semiconductor device in accordance with an embodiment of the present disclosure.

FIGS. 4A to 4J are simplified diagrams for describing a manufacturing method of a semiconductor device in accordance with an embodiment of the present disclosure.

FIGS. 5A to 5F are simplified diagrams for describing a manufacturing method of a semiconductor device in accordance with an embodiment of the present disclosure.

FIG. 6 is a configuration diagram of a semiconductor device in accordance with an embodiment of the present disclosure.

FIG. 7 is a configuration diagram of a semiconductor device in accordance with an embodiment of the present disclosure.

### DETAILED DESCRIPTION

Various embodiments of the present disclosure are directed to a semiconductor device having a stable structure and improved characteristics and a manufacturing method for the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical concepts of the present disclosure will be described with reference to the accompanying drawings.

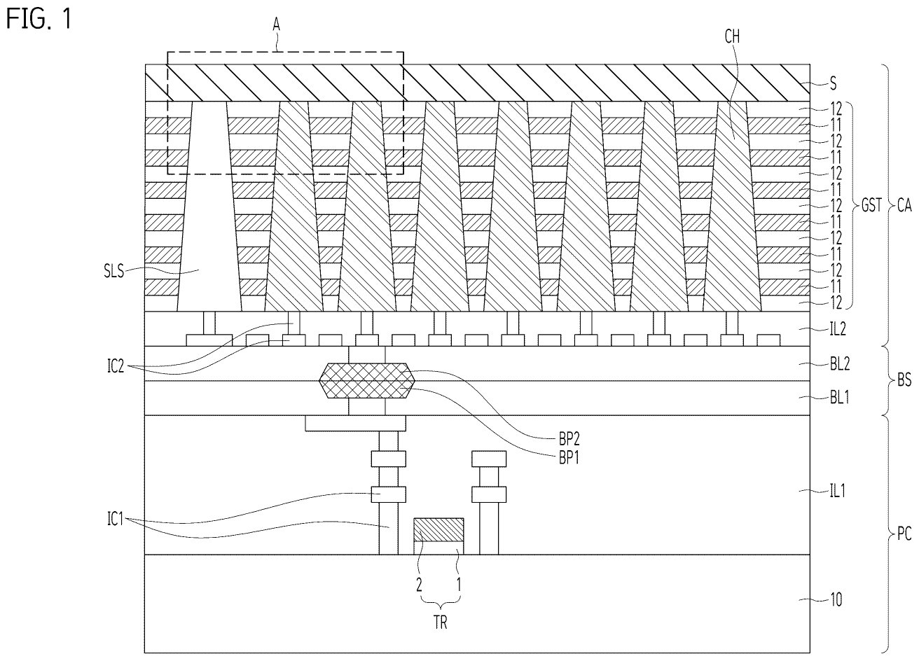

FIG. 1 is a simplified diagram illustrating the structure of a semiconductor device in accordance with an embodiment of the present disclosure.

Referring to FIG. 1, the semiconductor device may include a memory cell array CA, a peripheral circuit PC, and a bonding structure BS. The bonding structure BS may be located between the memory cell array CA and the peripheral circuit PC, and may electrically connect the memory cell array CA and the peripheral circuit PC to each other.

The memory cell array CA may include a gate structure GST, a channel structure CH, and a source structure S. The memory cell array CA may further include a second interlayer insulating layer IL2 and a second interconnection structure IC2.

The gate structure GST may include conductive layers 11 and insulating layers 12 that are alternately stacked. The conductive layers 11 may be gate lines such as word lines, drain select lines, and source select lines. For example, at least one conductive layer 11 located at the lowermost portion may be a drain select line, at least one conductive layer 11 located at the uppermost portion may be a source select line, and the remaining conductive layers 11 may be word lines. The conductive layers 11 may each include a conductive material such as polysilicon, tungsten, or molybdenum. The insulating layers 12 may be used to insulate the stacked gate lines from each other. The insulating layers 12 may each include oxide, nitride, air gap, or the like.

The channel structure CH may extend through the gate structure GST, and may be connected to the source structure S. A plurality of channel structures may be spaced apart from each other at regular intervals within the gate structure GST. A slit structure SLS may extend through the gate structure GST. The slit structure SLS may include a semiconductor material, an insulating material, a conductive material, or the like. The source structure 14 may be located over the gate structure GST. The source structure S may include a conductive material such as polysilicon or metal. In the illustrated embodiment, the source structure may be formed as a single layer.

A memory cell, a source select transistor, or a drain select transistor may be located in a region where the channel structure CH and the gate lines intersect each other. For example, at least one drain select transistor, memory cells, and at least one source select transistor that share the channel structure CH with each other may constitute one memory string.

The second interconnection structure IC2 may be located below the gate structure GST. The second interconnection structure IC2 may include a via, a wiring line, and the like, and may be located in the second interlayer insulating layer IL2. The second interconnection structure IC2 may be connected to the channel structure CH, a contact plug, and the like.

The peripheral circuit PC is used to drive the memory cell array CA, and may include a page buffer, a row decoder, a logic circuit, and the like. The peripheral circuit PC may include a substrate 10, a transistor TR, a first interconnection structure IC1, and a first interlayer insulating layer IL1. The transistor TR may be located on the substrate 10, and the transistor TR may include a gate insulating layer 1 and a gate electrode 2. The first interconnection structure IC1 may be connected to the transistor TR, and may be located in the first interlayer insulating layer IL1.

The bonding structure BS may be located between the gate structure GST and the peripheral circuit PC. The bonding structure BS may be located between the first interlayer insulating layer IL1 and the second interlayer insulating layer IL2. The bonding structure BS may include at least one of a first bonding layer BL1, a second bonding layer BL2, a first bonding pad BP1, and a second bonding pad BP2. The first bonding layer BL1 may include the first bonding pad BP1. The second bonding layer BL2 may include the second bonding pad BP2. The first and second bonding pads BP1 and BP2 may be configured to contact each other at a portion of the interface between the first and second bonding layers BL1 and BL2. The peripheral circuit PC and the memory cell array CA may be physically bonded to each other by the first bonding layer BL1 and the second bonding layer BL2. The first and second bonding layers BL1 and BL2 may each include silicon carbon nitride (SiCN), tetra ethyl ortho silicate (TEOS), or the like. The peripheral circuit PC and the memory cell array CA may be electrically connected to each other. For example, the peripheral circuit PC and the memory cell array CA may be electrically connected to each other through the first and second bonding pads BP1 and BP2. The first bonding pad BP1 and the second bonding pad BP2 may be electrically connected to the first interconnection structure IC1 and the second interconnection structure IC2, respectively.

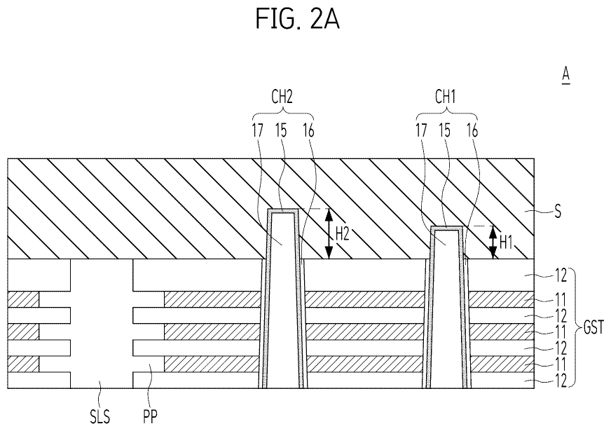

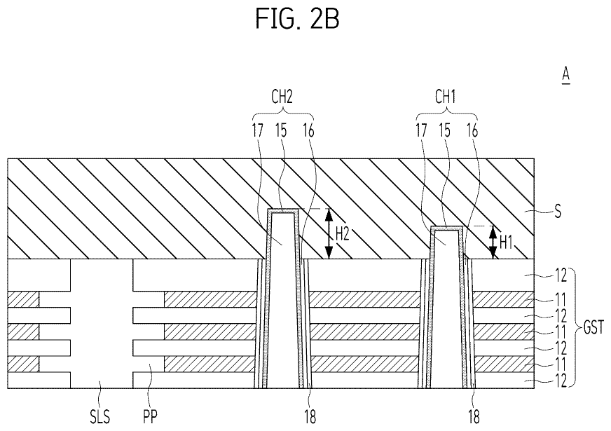

FIGS. 2A and 2B are simplified diagrams for describing the structure of a semiconductor device in accordance with an embodiment of the present disclosure. FIGS. 2A and 2B are enlarged views of region A of FIG. 1. Hereinafter, any content overlapping with previously described content may be omitted.

Referring to FIGS. 2A and 2B, the semiconductor device may include a gate structure GST, a first channel structure CH1, a second channel structure CH2, a source structure S, and a slit structure SLS.

Each of the first and second channel structures CH1 and CH2 may include a channel layer 15. Each of the first and second channel structures CH1 and CH2 may further include a memory layer 16 surrounding sidewalls of the channel layer 15 and an insulating core 17 located in the channel layer 15. The memory layer 16 may include at least one of a tunneling layer, a data storage layer, and a blocking layer. For example, the data storage layer may include polysilicon, a floating gate, nitride, a charge trap material, a variable resistance material, or the like.

The channel layer 15 may protrude into the source structure S. The channel layer 15 may be in direct contact with the source structure S. The channel layer 15 of the first channel structure CH1 may protrude from an upper surface of the gate structure GST by a first height H1.

The channel layer 15 of the second channel structure CH2 may protrude from the upper surface of the gate structure GST by a second height H2. The first and second heights H1 and H2 may be different from each other. In the illustrated embodiment, the second height H2 is larger than the first height H1.

The slit structure SLS may include protrusion portions on sidewalls thereof. The protrusion portions may protrude toward the conductive layers 11. An upper surface of the slit structure SLS may be located at a lower level than the respective upper surfaces of the first and second channel structures CH1 and CH2. The upper surface of the slit structure SLS may be located on the same plane as the upper surface of the gate structure GST. The slit structure SLS may not protrude into the source structure S.

Referring to FIG. 2B, the semiconductor device may further include a protective layer 18. The protective layer 18 may surround the sidewalls of the channel layer 15 with the memory layer 16 interposed therebetween. The protective layer 18 may include oxide. The protective layer 18 may include silicon oxide (SiO₂).

According to the structure described above, the upper surface of the first channel structure CH1 and the upper surface of the second channel structure CH2 may be located at different levels. The upper surface of the slit structure SLS may be located at a lower level than the upper surfaces of the first channel structure CH1 and the second channel structure CH2. The heights at which the first and second channel structures CH1 and CH2 protrude may be controlled to a predetermined value or less. A level difference between the upper surfaces of the first channel structure CH1 and the second channel structure CH2 may be controlled to be a predetermined value or less.

A level difference between the upper surfaces of the channel structures CH1 and CH2 and the upper surface of the slit structure SLS may be controlled to be a predetermined value or less. Accordingly, it is possible to improve height uniformity of the channel structures CH1 and CH2, and it is possible to make the characteristics of memory strings uniform.

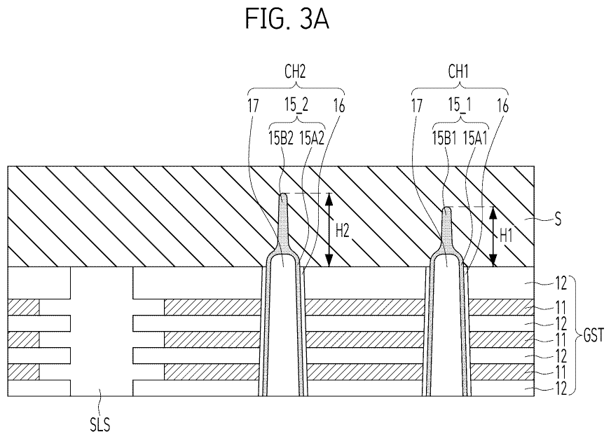

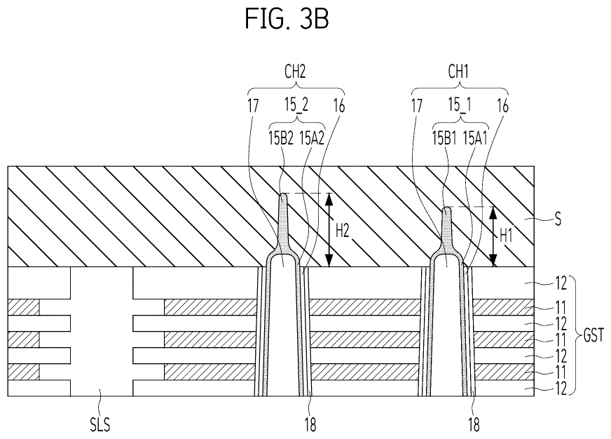

FIGS. 3A and 3B are simplified diagrams for describing the structure of a semiconductor device in accordance with an embodiment of the present disclosure. FIGS. 3A and 3B are enlarged views of region A of FIG. 1. Hereinafter, any content overlapping with previously described content may be omitted.

Referring to FIGS. 3A and 3B, the semiconductor device may include a gate structure GST, a first channel structure CH1, a second channel structure CH2, a source structure S, and a slit structure SLS. The first channel structure CH1 may include a first channel layer 15_1, and the second channel structure CH2 may include a second channel layer 15_2.

The first channel layer 15_1 may include a first penetration portion 15A1 and a first tip 15B1. The first penetration portion 15A1 may extend through the gate structure GST. A portion of the first penetration portion 15A1 close to the first tip 15B1 may protrude from a surface of the gate structure GST. The first tip 15B1 may be connected to the first penetration portion 15A1, and may protrude into the source structure S. The first tip 15B1 may have a smaller width than the first penetration portion 15A1. The first channel layer 15_1 may have a step at a portion where the first penetration portion 15A1 and the first tip 15B1 are connected to each other.

An insulating core 17 may be located in the first penetration portion 15A1, and may not be located in the first tip 15B1. The first penetration portion 15A1 may be surrounded by a memory layer 16. The portion of the first penetration portion 15A1 close to the first tip 15B1 may protrude from the surface of the gate structure GST, and may not be surrounded by the memory layer 16. The first tip 15B1 may not be surrounded by the memory layer 16. The first tip 15B1 may be in direct contact with the source structure S.

The second channel layer 15_2 may include a second penetration portion 15A2 and a second tip 15B2. The second penetration portion 15A2 may extend through the gate structure GST. A portion of the second penetration portion 15A2 close to the second tip 15B2 may protrude from the surface of the gate structure GST. The second tip 15B2 may be connected to the second penetration portion 15A2, and may protrude into the source structure S. The second tip 15B2 may have a smaller width than the second penetration portion 15A2. The second channel layer 15_2 may have a step at a portion where the second penetration portion 15A2 and the second tip 15B2 are connected to each other. A step located on a sidewall of the first channel layer 15_1 and a step located on a sidewall of the second channel layer 15_2 may be located at substantially the same level.

An insulating core 17 may be located in the second penetration portion 15A2, and may not be located in the second tip 15B2. The second penetration portion 15A2 may be surrounded by a memory layer 16. The portion of the second penetration portion 15A2 close to the second tip 15B2 may protrude from the surface of the gate structure

GST, and may not be surrounded by the memory layer 16. The second tip 15B2 may not be surrounded by the memory layer 16. The second tip 15B2 may be in direct contact with the source structure S.

The first channel structure CH1 may protrude from an upper surface of the gate structure GST by a first height H1. The second channel structure CH2 may protrude from the upper surface of the gate structure GST by a second height H2. The first height H1 and the second height H2 may be different from each other. The first penetration portion 15A1 and the second penetration portion 15A2 may have substantially the same height. The first tip 15B1 and the second tip 15B2 may have different heights. Accordingly, a difference between the first and second heights H1 and H2 may be due to a height difference between the first and second tips 15B1 and 15B2.

Referring to FIG. 3B, the semiconductor device may further include a protective layer 18. The protective layer 18 may surround the first penetration portion 15A1, and may not surround the portion of the first penetration portion 15A1 close to the first tip 15B1. The first tip 15B1 may not be surrounded by the protective layer 18. The protective layer 18 may surround the second penetration portion 15A2, and may not surround the portion of the second penetration portion 15A2 close to the second tip 15B2. The second tip 15B2 may not be surrounded by the protective layer 18.

According to the structure described above, it is possible to improve height uniformity of the channel structures CH1 and CH2, and it is possible to make the characteristics of memory strings uniform. In addition, as the channel structures CH1 and CH2 include the tips 15B1 and 15B2, respectively, a channel length may be increased and a cell current may be increased.

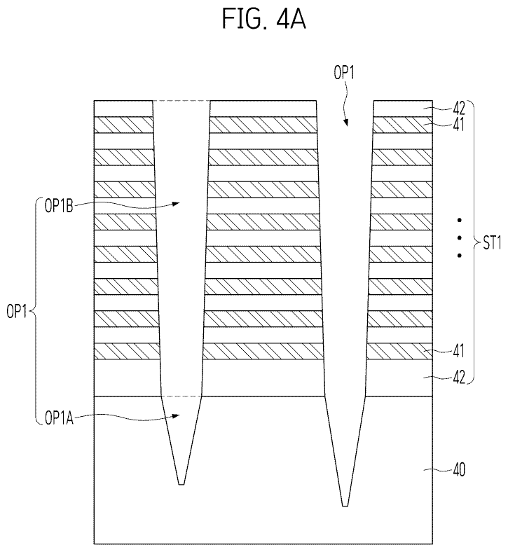

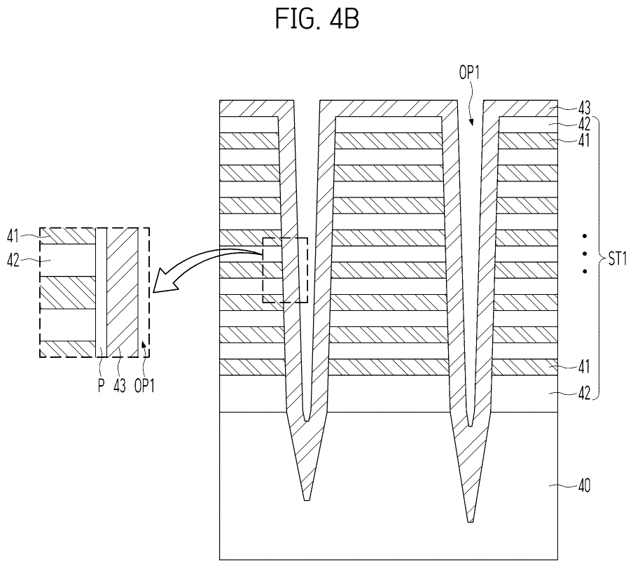

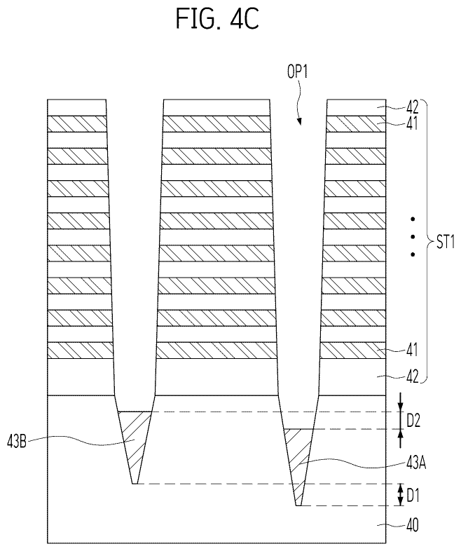

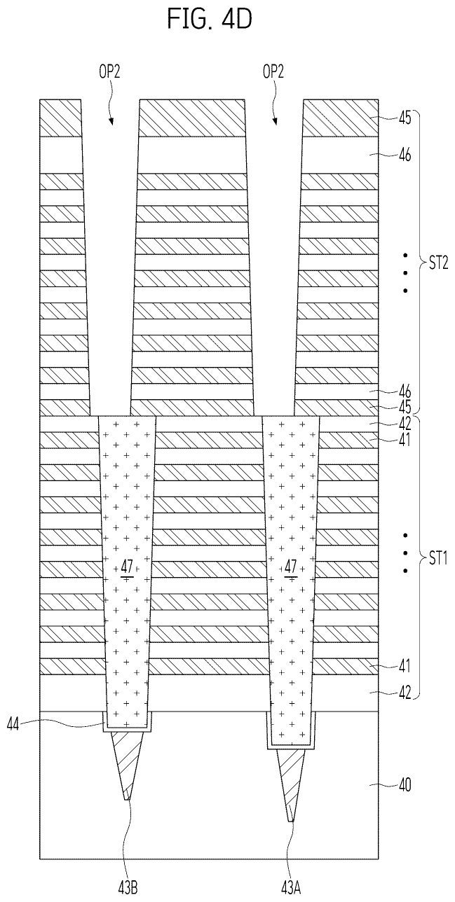

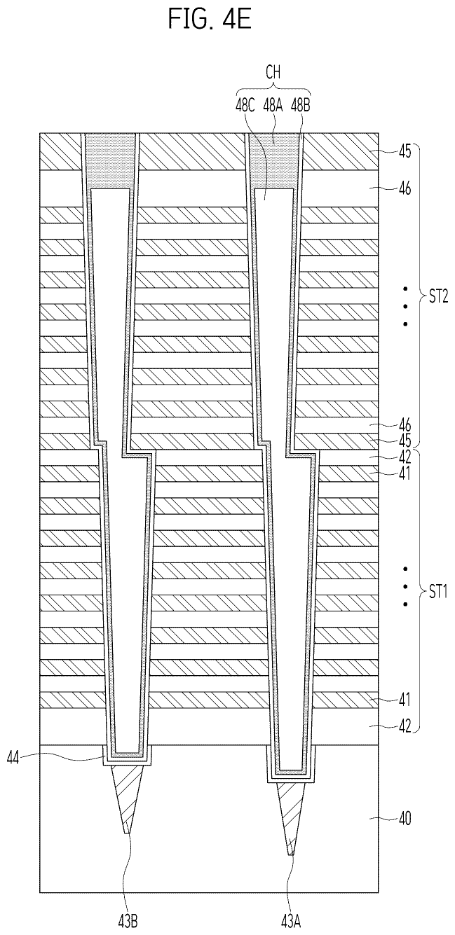

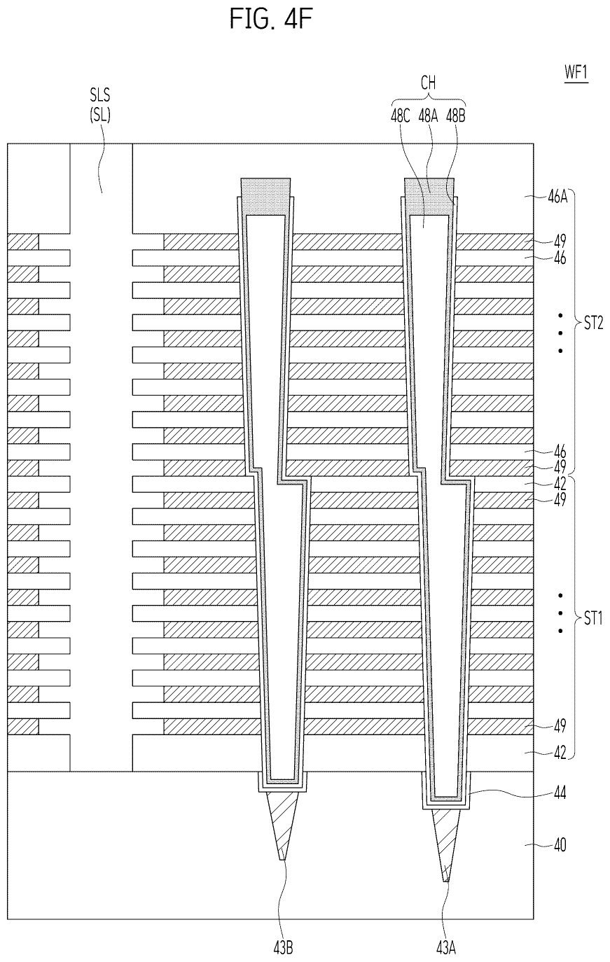

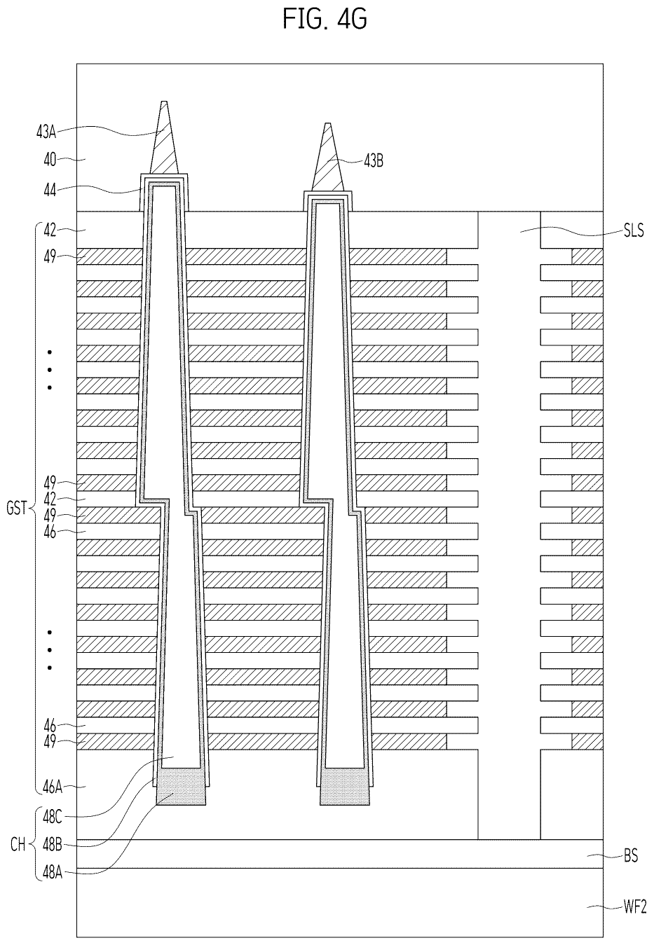

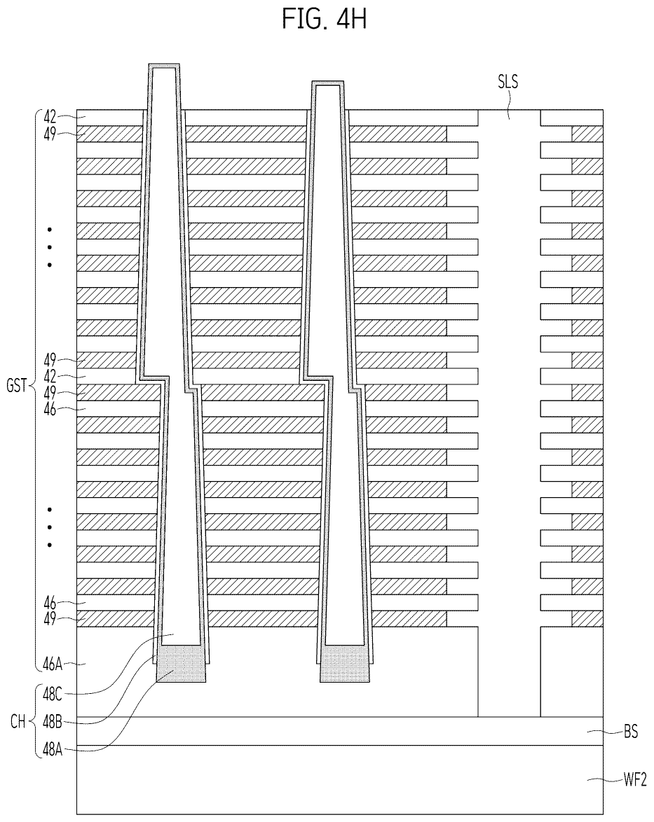

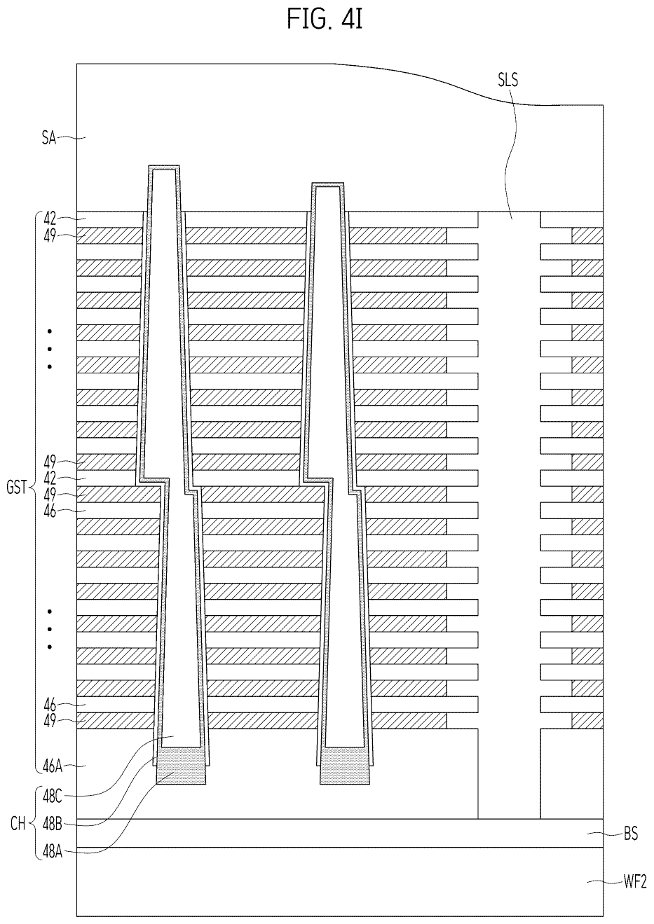

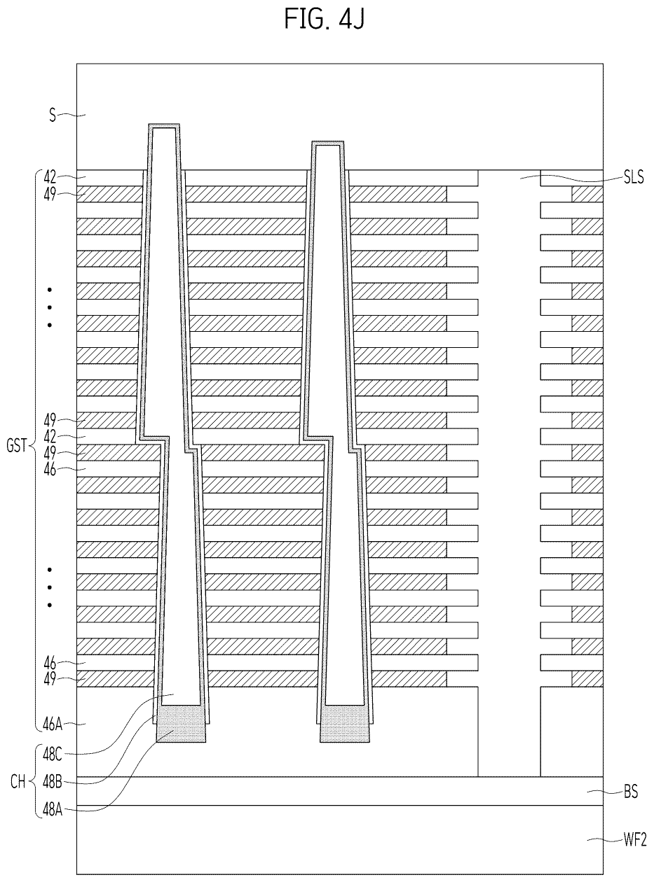

FIGS. 4A to 4J are simplified diagrams for describing a manufacturing method for making the inventive semiconductor device in accordance with an embodiment of the present disclosure. Hereinafter, any content overlapping with previously described content may be omitted.

Referring to FIG. 4A, a first stack ST1 may be formed over a substrate 40. The first stack ST1 may include first material layers 41 and second material layers 42 that are alternately stacked. For example, the first material layers 41 may each include a material having a high etching selectivity with respect to the second material layers 42. The first material layers 41 may be used to form gate lines.

For example, the first material layers 41 may each include a sacrificial material such as nitride or a conductive material such as polysilicon or metal. The second material layers 42 may each include an insulating material for insulating the stacked gate lines from each other. The second material layers 42 may each include oxide, nitride, air gap, or the like.

Subsequently, first openings OP1 extending into the substrate 40 through the first stack ST1 may be formed. Each of the first openings OP1 may include a first portion OP1A located in the substrate 40 and a second portion OP1B located in the first stack ST1. The first portion OP1A and the second portion OP1B may each have a cross section with a tapered shape. A difference between an upper width and a lower width of the first portion OP1A may be greater than a difference between an upper width and a lower width of the second portion OP1B. An end of the first portion OP1A may have a tip shape.

The first openings OP1 may have different depths. The second portions OP1B are formed in the first stack ST1, and may thus have substantially the same depth. Because there is no separate etch stop layer in the substrate 40 when performing an etching process for forming the first openings OP1, the substrate 40 may be deeply etched and may be etched at non-uniform depths. Accordingly, the first portions OP1A may have different depths. A depth difference between the first openings OP1 may be caused by a depth difference between the first portions OP1A of the first openings OP1.

Referring to FIG. 4B, a gap-fill layer 43 may be formed. The gap-fill layer 43 may be formed along inner surfaces of the first openings OP1. The gap-fill layer 43 may include a material having an etching selectivity with respect to the first material layers 41 and the second material layers 42. For example, the gap-fill layer 43 may include polysilicon.

For reference, before the gap-fill layer 43 is formed, a protective layer P may be formed. The protective layer P may be formed along the inner surfaces of the first openings OP1. The protective layer may be formed to have a smaller thickness than the gap-fill layer 43. For example, the protective layer P may be formed to have a thickness of 100 Å or less. The protective layer P may include, for example, silicon oxide (SiO₂).

Referring to FIG. 4C, gap-fill patterns 43A and 43B may be

formed by etching the gap-fill layer 43. For example, the gap-fill layer 43 may be etched using a wet etching process. When the gap-fill layer 43 is etched, the first stack ST may be protected through the protective layer P. In a process of etching the gap-fill layer 43, the protective layer P may be etched together or may at least partially remain.

Lower portions of the first openings OP1 may be filled with the gap-fill patterns 43A and 43B. The gap-fill patterns 43A and 43B may be located in the substrate 40. The upper surfaces of the gap-fill patterns 43A and 43B may be located at substantially the same level as an upper surface of the substrate 40 or located at a lower level than the upper surface of the substrate 40. Accordingly, the depths of the first openings OP1 may be reduced by the heights of the gap-fill patterns 43A and 43B.

A first gap-fill pattern 43A may be formed in the first opening OP1 having a relatively greater depth, and a second gap-fill pattern 43B may be formed in the first opening OP1 having a relatively smaller depth. A lower surface of the first gap-fill pattern 43A may be located at a lower level than a lower surface of the second gap-fill pattern 43B, and an upper surface of the first gap-fill pattern 43A may be located at a lower level than an upper surface of the second gap-fill pattern 43B.

The lower surface of the first gap-fill pattern 43A and the lower surface of the second gap-fill pattern 43B may have a first difference D1 therebetween. The upper surface of the first gap-fill pattern 43A and the upper surface of the second gap-fill pattern 43B may have a second difference D2 therebetween. Depending on a difference in deposition/etching environment due to the depth difference between the first portions OP1A, the second difference D2 may be smaller than the first difference D1. Accordingly, an important effect obtained by forming the gap-fill patterns 43A and 43B, is the reducing of the depth difference between the first openings OP1. That is, in this way, the inventive method achieves improved depth uniformity of the first openings OP1.

Referring to FIG. 4D, an oxidation pattern 44 may be formed by performing an oxidation process or an annealing process. For example, a dry or wet oxidation process may be performed, and the oxidation patterns 44 may be formed by selectively oxidizing surfaces of the gap-fill patterns 43A and 43B and the substrate 40.

Subsequently, sacrificial layers 47 may be formed in the first openings OP1. The sacrificial layers 47 may each include a material having an etching selectivity with respect to the first material layers 41 and the second material layers 42. For example, the sacrificial layers 47 may each include titanium nitride, tungsten, carbon, or the like. When the sacrificial layers 47 are formed without forming the oxidation patterns 44, the sacrificial layers 47 may react with the gap-fill patterns 43A and 43B, and heterogeneous materials may be generated. Hence, according to an embodiment of the present disclosure, it is possible to prevent the gap-fill patterns 43A and 43B from reacting with the sacrificial layers 47 through the oxidation patterns 44 and prevent heterogeneous materials from being generated.

Subsequently, a second stack ST2 may be formed over the first stack ST1. The second stack ST2 may include third and fourth material layers 45 and 46 that are alternately stacked. For example, the third material layers 45 may each include a material having a high etching selectivity with respect to the fourth material layers 46. The third material layers 45 may be used to form gate lines. For example, the third material layers 45 may each include a sacrificial material such as nitride or a conductive material such as polysilicon or metal. The fourth material layers 46 may each include an insulating material for insulating the stacked gate lines from each other. The fourth material layers 46 may each include oxide, nitride, air gap, or the like.

Subsequently, second openings OP2 extending through the second stack ST2 and connected to the first openings OP1 may be formed. The second openings OP2 may each have a cross section with a tapered shape. The second openings OP2 may be aligned or misaligned with the first openings OP1.

For reference, it is also possible to additionally form a third stack ST3 over the second stack ST2, and third openings extending through the third stack ST3 and connected to the second openings OP2 may be formed. The number of stacks that are stacked may be adjusted depending on the degree of integration of a memory.

Referring to FIG. 4E, the sacrificial layers 47 may be removed. In a process of removing the sacrificial layers 47, the oxidation patterns 44 may be partially etched. Subsequently, channel structures CH may be formed in the first openings OP1 and the second openings OP2. For example, a memory layer 48B may be formed in the first and second openings OP1 and OP2. A channel layer 48A may then be formed conformally over the memory layer 48B and an insulating core 48C may be formed in the remaining space of the first and second openings OP1 and OP2.

Because the channel structures CH are formed over the gap-fill patterns 43A and 43B and the oxidation patterns 44, the channel structures CH may be formed at heights lower than the depths of the first openings OP1 that are initially formed. Compared to a case where the gap-fill patterns 43A and 43B and the oxidation patterns 44 are not formed, a depth of a portion of the channel structure CH protruding into the substrate 40 may be reduced.

Referring to FIG. 4F, the first material layers 41 and the third material layers 45 may be replaced with fifth material layers 49. The fifth material layers 49 are used to form gate lines, and may each include a metal such as tungsten or molybdenum. For example, a slit SL penetrating through the first stack ST1 and the second stack ST2 may be formed, and the first material layers 41 and the third material layers 45 may be removed through the slit SL. Subsequently, the fifth material layers 49 may be respectively formed in regions where the first material layers 41 and the third material layers 45 are removed. Subsequently, a slit structure SLS may be formed in the slit SL.

Consequently, a gate structure GST including the fifth material layers 49 and the second material layers 42 that are alternately stacked and the fifth material layers 49 and the fourth material layers 46 that are alternately stacked may be formed.

For reference, before the first and third material layers 41 and 45 are replaced with the fifth material layers 49, a process of patterning the first stack ST1 and the second stack ST2 in a staircase shape may be additionally performed. In this process, the uppermost third material layer 45 may be removed, and a fourth material layer may be additionally formed, such that the uppermost fourth material layer 46A may be formed. In addition, an upper portion of the channel layer 48A and an upper portion of the memory layer 48B may be partially etched.

For reference, when the first material layers 41 and the third material layers 45 each include a conductive material, a replacement process may be omitted. In such a case, the first material layers 41 and the third material layers 45 may be the gate lines, and the first stack ST1 and the second stack ST2 may be the gate structure GST.

Subsequently, although not illustrated in FIG. 4F, an interconnection structure, a bonding pad, and the like, may be formed. Consequently, a first wafer WF1 including the gate structure GST and the channel structures CH may be formed. The first wafer WF1 may include a memory cell array.

Referring to FIG. 4G, the first wafer WF1 including the memory cell array and a second wafer WF2 including a peripheral circuit may be bonded to each other. The first wafer WF1 and the second wafer WF2 may be bonded to each other through a bonding structure BS. The first wafer WF1 may be reversed in the bonding process so that the substrate 40 is located over the gate structure GST.

Referring to FIG. 4H, the substrate 40 and the gap-fill patterns 43A and 43B may be removed. For example, the substrate 40 may be removed using a grinding process, a chemical mechanical polish (CMP) process, a wet etching process, or the like. When the gap-fill patterns 43A and 43B each include polysilicon, the substrate 40 and the gap-fill patterns 43A and 43B may be removed simultaneously. By removing the substrate 40 and the gap-fill patterns 43A and 43B, the oxidation patterns 44 may be exposed. The oxidation patterns 44 may protrude from a surface of the gate structure GST.

For reference, the protective layer P (as shown in FIG. 4B) may exist between the substrate 40 and the gap-fill patterns 43A and 43B. In such a case, i.e., when the protective layer P is used, the protective layer P is formed to have a small thickness, and thus, the protective layer P and the gap-fill patterns 43A and 43B may be removed together during the process of removing the substrate 40.

Subsequently, the oxidation patterns 44 and the memory layer 48B may be removed. The oxidation patterns 44 and the memory layer 48B may be removed simultaneously or be removed through separate processes. In a process of removing the memory layer 48B, the uppermost fourth material layer 46A may be partially etched.

Through this, the channel layer 48A may be exposed as shown in FIG. 4H. Because the lower portions of the first openings OP1 are filled with the gap-fill patterns 43A and 43B and the oxidation patterns 44 in the previous process, a height of a portion of the channel layer 48A protruding from a surface of the gate structure GST may be relatively low.

Subsequently, the channel layer 48A may be doped with impurities. The impurities may form a junction in the channel layer 48A. The impurities may be used to form a junction of a source select transistor. For example, the impurities may be doped in the channel layer 48A protruding from the surface of the gate structure GST using an ion implantation process.

Referring to FIG. 4I, a source layer SA may be formed over the gate structure GST. For example, a polysilicon layer may be deposited on the gate structure GST, and an annealing process may be performed on the polysilicon layer. For example, the annealing process may be a laser annealing process.

Through the laser annealing process, the polysilicon layer may be melted, and a silicon layer having a single crystal or a crystal structure close to the single crystal may be formed. In a process of melting the polysilicon layer, polysilicon may flow down due to a height difference between the channel structures CH and a height difference between the channel structures CH and the slit structure SLS. Unlike the channel structures CH protruding from the surface of the gate structure GST, an upper surface of the slit structure SLS may have substantially the same height as the surface of the gate structure GST. Accordingly, the melted polysilicon may flow down toward the slit structure SLS located at a relative low level. When a height difference between an upper surface of the channel structure CH and the upper surface of the slit structure SLS is great, the polysilicon flows down, and accordingly, the channel structure CH may be exposed, and an excessive amount of hydrogen may be injected into the exposed channel structure CH in a subsequent passivation process, which may cause a defect. However, according to an embodiment of the present disclosure, a height of a portion of the channel structure CH protruding from the surface of the gate structure GST may be reduced, and thus, a less amount of polysilicon flows down. Accordingly, the channel structure CH may not be exposed, and an excessive amount of hydrogen may not be injected into the channel structure CH.

Through the laser annealing process, the impurities doped in the channel layer 48A may be activated, and the junction may be formed in the channel layer 48A. When the height of the portion of the channel structure CH protruding from the surface of the gate structure GST is great, relatively great activation energy is required to activate the impurities. Accordingly, in the case of the channel structure CH whose height of the portion protruding from the surface of the gate structure GST is great, activation energy may be insufficient. According to an embodiment of the present disclosure, the height of the portion of the channel structure CH protruding from the surface of the gate structure GST may be reduced, and thus, a problem in which the activation energy is insufficient may be improved.

Referring to FIG. 4J, a source structure S may be formed by planarizing the source layer SA. For example, the source layer SA may be planarized using a CMP process.

According to the process described above, the heights of the channel structures CH protruding from the surface of the gate structure GST may be reduced, and the height difference between the channel structures CH may be reduced. Accordingly, a problem in which an excessive amount of hydrogen is injected into the channel structures CH may be improved. Also, a problem in which the activation energy is insufficient may be improved.

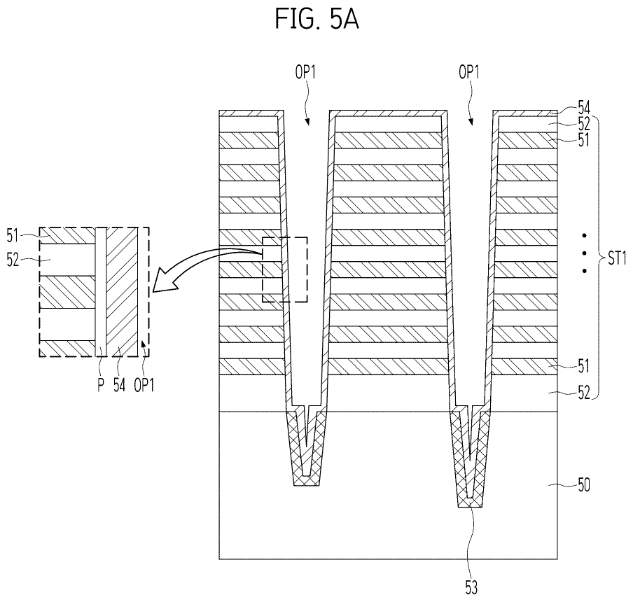

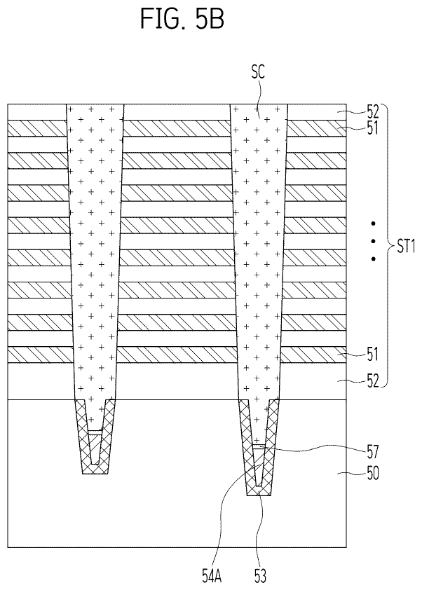

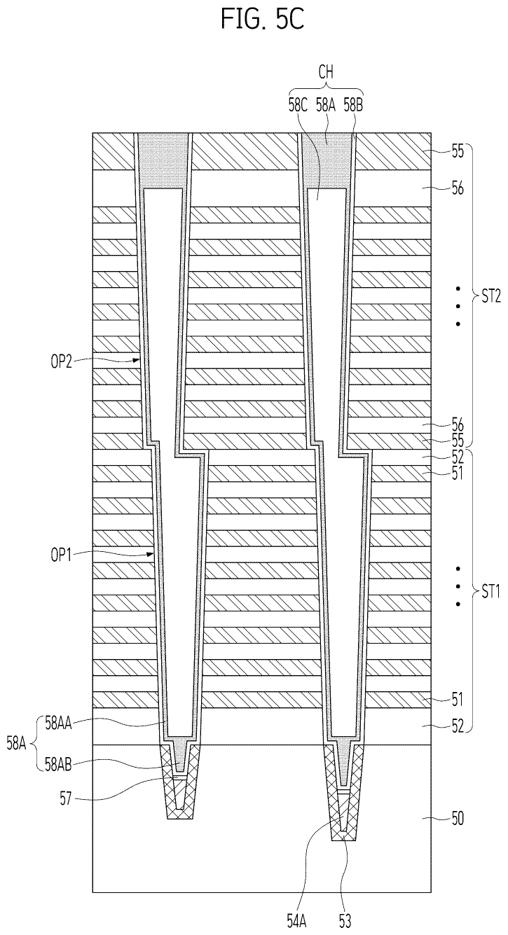

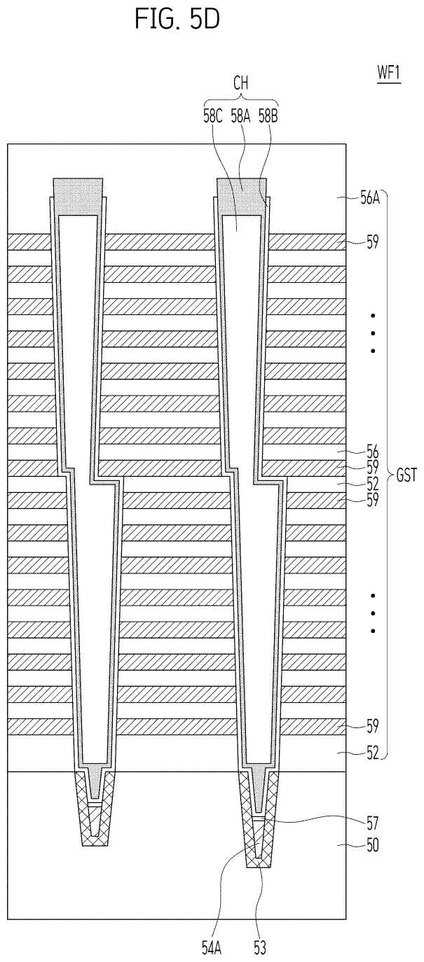

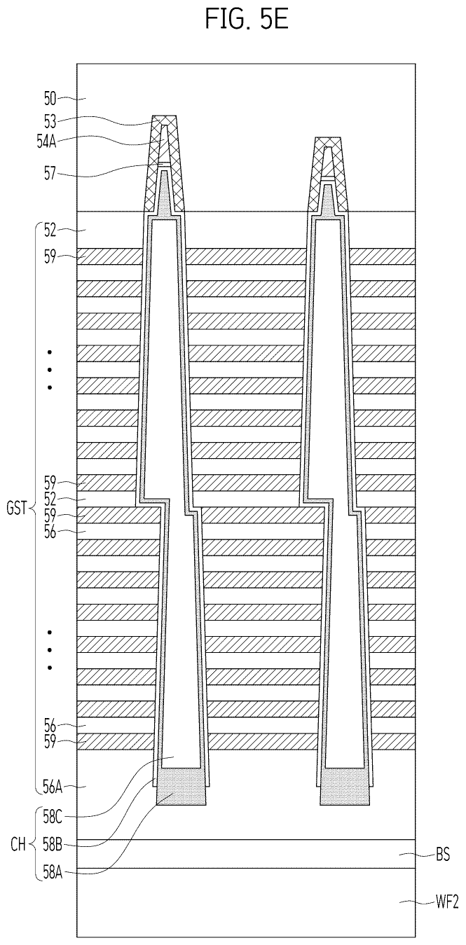

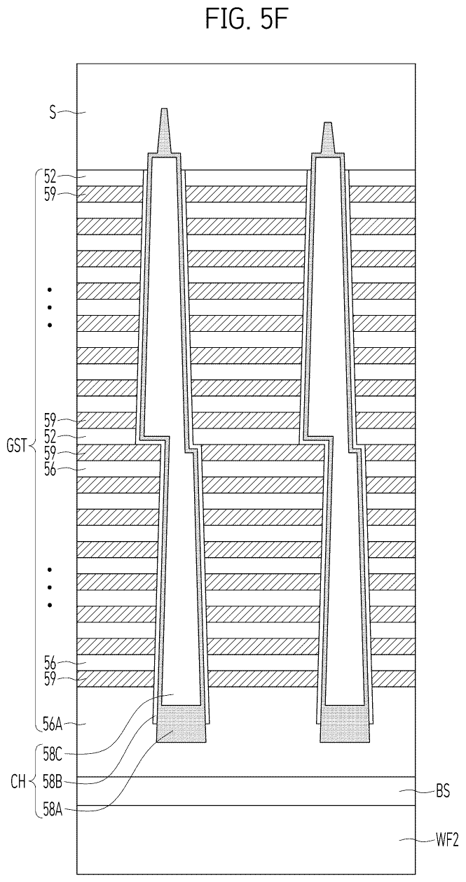

FIGS. 5A to 5F are simplified diagrams for describing a manufacturing method of a semiconductor device in accordance with an embodiment of the present disclosure. Hereinafter, any content overlapping with previously described content may be omitted.

Referring to FIG. 5A, a first stack ST1 may be formed over a substrate 50. The first stack ST1 may include first material layers 51 and second material layers 52 that are alternately stacked. The first material layers 51 may be sacrificial layers for forming gate lines, and the second material layers 52 may be insulating layers for insulating the stacked gate lines from each other.

Subsequently, first openings OP1 extending into the substrate 50 through the first stack ST1 may be formed. The first openings OP1 may have different depths.

Subsequently, buffer patterns 53 may be formed in the first openings OP1. The buffer patterns 53 may be formed by oxidizing a surface of the substrate 50 exposed through the first openings OP1 using an oxidation process. For example, the substrate 50 may be selectively oxidized using a dry or wet oxidation process.

Subsequently, a gap-fill layer 54 may be formed in the first openings OP1. The gap-fill layer 54 may be formed along inner surfaces of the first openings OP1. For reference, before the gap-fill layer 54 is formed, a protective layer P may be formed.

Referring to FIG. 5B, gap-fill patterns 54A may be formed by etching the gap-fill layer 54. Through this, the gap-fill patterns 54A may be formed in the buffer patterns 53, and depths of the first openings OP1 may be reduced by heights of the gap-fill patterns 54A. By forming the gap-fill patterns 54A, a depth difference between the first openings OP1 may be reduced.

Subsequently, oxidation patterns 57 may be formed by performing an oxidation process or an annealing process. For example, a dry or wet oxidation process may be performed, and the oxidation patterns 57 may be formed by selectively oxidizing surfaces of the gap-fill patterns 54A. Subsequently, sacrificial layers SC may be formed in the first openings OP1.

Referring to FIG. 5C, a second stack ST2 may be formed over the first stack ST1. The second stack ST2 may include third material layers 55 and fourth material layers 56 that are alternately stacked. Subsequently, second openings extending through the second stack ST2 and connected to the first openings OP1 are formed. Subsequently, the sacrificial layers SC may be removed from the first openings OP1.

Subsequently, channel structures CH may be formed in the first openings OP1 and the second openings. The channel structures CH may extend through the first and second stacks ST1 and ST2, and may extend into the buffer patterns 53. Each of the channel structures CH may include a channel layer 58A, a memory layer 58B, and an insulating core 58C. The channel layer 58A may include a penetration portion 58AA and a tip 58AB. The penetration portion 58AA may extend through the first stack ST1 and the second stack ST2. The tip 58AB may be connected to the penetration portion 58AA, and may be located in the buffer pattern 53. The tip 58AB may have a shape whose width decreases as a distance from the penetration portion 58AA increases.

Referring to FIG. 5D, the first material layers 51 and the third material layers 55 may be replaced with fifth material layers 59. Through this, a gate structure GST including the fifth material layers 59 and the second material layers 52 that are alternately stacked and the fifth material layers 59 and the fourth material layers 56 that are alternately stacked may be formed. In this process, the uppermost fourth material layer 56 may be removed, and a fourth material layer 56A may be newly formed. An upper portion of the channel layer 58A and an upper portion of the memory layer 58B may be partially etched. Consequently, a first wafer WF1 including the gate structure GST and the channel structures CH may be formed. The first wafer WF1 may include a memory cell array.

Referring to FIG. 5E, the first wafer WF1 including the memory cell array and a second wafer WF2 including a peripheral circuit may be bonded to each other. The first wafer WF1 and the second wafer WF2 may be bonded to each other through a bonding structure BS. The first wafer WF1 may be reversed in the bonding process, and the substrate 50 may be located over the gate structure GST.

Referring to FIG. 5F, the substrate 50 may be removed, and the buffer patterns 53 may be exposed. Subsequently, the buffer patterns 53 may be removed, and the gap-fill patterns 54A and memory layers 58B may be exposed. Subsequently, the gap-fill patterns 54A may be removed, and the memory layers 58B may be removed. Through this, the channel layers 58A may be exposed. In a process of removing the memory layer 58B, the uppermost fourth material layer 56A may be partially etched.

Subsequently, the channel layer 58A may be doped with impurities. Subsequently, a source layer may be formed over the gate structure GST, and a laser annealing process may be performed. Through this, the source layer may be melted and single-crystallized, and the impurities in the channel layer 58A may be activated. In a process of melting the source layer, portions of the tips 58AB may be melted, and heights of the tips 58AB may be reduced. Subsequently, a source structure S may be formed by planarizing the source layer.

According to the process described above, the heights of the channel structures CH protruding from the surface of the gate structure GST may be reduced, and the height difference between the channel structures CH may be reduced. Accordingly, a problem in which an excessive amount of hydrogen is injected into the channel structures CH may be improved. Also, a problem in which the activation energy is insufficient may be improved.

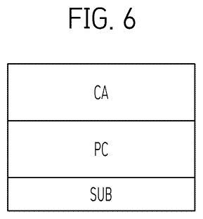

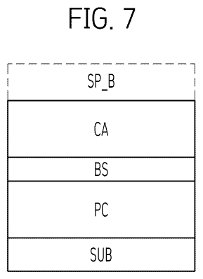

The structures and the manufacturing methods according to the above-described embodiments may be applied to semiconductor devices having various structures. FIGS. 6 and 7 illustrate schematic configurations of semiconductor devices to which the above-described embodiments are applicable.

FIG. 6 is a configuration diagram of a semiconductor device in accordance with an embodiment of the present disclosure.

Referring to FIG. 6, the semiconductor device may include a substrate SUB, a peripheral circuit PC, and a memory cell array CA. For example, the peripheral circuit PC and the memory cell array CA may be formed over the same substrate.

The substrate SUB may include a semiconductor material. For example, the semiconductor material may include at least one of a group IV semiconductor, a group III-V compound semiconductor, and a group II-VI compound semiconductor. For example, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. For example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method, and may partially include metal. The substrate SUB may have a single crystalline, polycrystalline, or amorphous state. The substrate SUB may include group II, group III, group IV, group V, or group VI impurities. For example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. For example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operating voltage and may include a contact plug, a wiring line, and the like.

The memory cell array CA may include memory cells. For example, the memory cell array CA may include memory strings connected between a source line and a bit line, and each memory string may include stacked memory cells. For example, the memory cell array CA may include memory cells connected between a word line and the bit line. The memory cell array CA may further include an interconnection structure.

FIG. 7 is a configuration diagram of a semiconductor device in accordance with an embodiment of the present disclosure.

Referring to FIG. 7, the semiconductor device may include a substrate SUB, a peripheral circuit PC, a bonding structure BS, and a memory cell array CA. For example, the peripheral circuit PC and the memory cell array CA may be formed on separate substrates, respectively, and then bonded to each other. The semiconductor device may further include a support base SP_B.

The substrate SUB may be used as a support in a process of forming the peripheral circuit PC. The support base SP_B may be used as a support in a process of forming the memory cell array CA. For example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell CA array.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. For example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be directly connected to each other without a bonding pad. For example, a bonding layer included in the memory cell array CA and a bonding layer included in the peripheral circuit PC may be bonded to each other to form a bonding interface, and an interconnection structure included in the memory cell array CA and an interconnection structure included the peripheral circuit PC may be directly connected to each other. Through this, contact plugs, wiring lines, and the like, formed on different wafers may be electrically connected to each other without a separate bonding pad.

Other configurations may be the same as or similar to those described above with reference to FIG. 6.

It is also possible for the semiconductor device to have a structure in which embodiments described above with reference to FIGS. 6 and 7 are combined with each other or have a partially modified structure. In embodiments described with reference to FIGS. 6 and 7, locations of the memory cell array CA and the peripheral circuit PC may be changed. At least one memory cell array CA and/or at least one peripheral circuit PC may be additionally bonded to each other in an embodiment described with reference to FIG. 6. For example, a portion of the peripheral circuit PC may be located in the memory cell array CA.

Although embodiments according to the technical concepts of the present disclosure have been described above with reference to the accompanying drawings, this is only for describing the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical concepts of the present disclosure defined in the following claims, and it should be construed that these substitutions, modifications, changes, and combinations belong to the scope of the present disclosure. Furthermore, the embodiments may be combined to form additional embodiments.

What is claimed is:

1. A semiconductor device comprising:
a source structure;
a gate structure including conductive layers and insulating layers that are alternately stacked;
a first channel layer including a first penetration portion extending through the gate structure and a first tip having a smaller width than the first penetration portion and protruding into the source structure;
a second channel layer including a second penetration portion extending through the gate structure and a second tip having a smaller width than the second penetration portion and protruding into the source structure; and
a slit structure extending through the gate structure,
wherein the first tip and the second tip have different heights.

2. The semiconductor device of claim 1, wherein the first channel layer has a step at a portion where the first penetration portion and the first tip are connected to each other.

3. The semiconductor device of claim 2, wherein the second channel layer has a step at a portion where the second penetration portion and the second tip are connected to each other, and
wherein the step of the first channel layer and the step of the second channel layer are located at substantially the same level.

4. The semiconductor device of claim 1, wherein a portion of the first penetration portion close to the first tip protrudes from a surface of the gate structure.

5. The semiconductor device of claim 1, wherein the first penetration portion and the second penetration portion have substantially the same height.

6. The semiconductor device of claim 1, further comprising:
a first insulating core located in the first penetration portion; and
a second insulating core located in the second penetration portion.

7. The semiconductor device of claim 1, further comprising a protective layer surrounding a sidewall of the first channel layer.

8. The semiconductor device of claim 7, wherein the protective layer includes oxide.

9. The semiconductor device of claim 1, wherein an upper surface of the slit structure is located at a lower level than an upper surface of the first channel layer.

10. The semiconductor device of claim 1, further comprising:
a peripheral circuit; and
a bonding structure located between the gate structure and the peripheral circuit.

11. A manufacturing method of a semiconductor device, the manufacturing method comprising:
forming a stack over a substrate, the stack including first material layers and second material layers that are alternately stacked;
forming an opening extending into the substrate through the stack;
forming a gap-fill pattern at a lower portion of the opening;
forming a channel structure in the opening where the gap-fill pattern is formed;
removing the substrate so that the channel structure protrudes from a surface of the stack;
removing the gap-fill pattern; and
forming a source structure connected to the channel structure.

12. The manufacturing method of claim 11, further comprising, before forming the gap-fill pattern, forming a protective layer in the opening.

13. The manufacturing method of claim 11, further comprising forming an oxidation pattern by oxidizing a surface of the gap-fill pattern.

14. The manufacturing method of claim 13, wherein the oxidation pattern is removed after the substrate and the gap-fill pattern are removed.

15. The manufacturing method of claim 11, wherein forming the channel structure comprises:
forming a memory layer in the opening; and
forming a channel layer in the memory layer.

16. The manufacturing method of claim 15, further comprising removing the memory layer to expose the channel layer.

17. The manufacturing method of claim 11, further comprising:
forming a slit extending through the stack;
replacing the first material layers with third material layers through the slit; and
forming a slit structure in the slit.

18. The manufacturing method of claim 17, wherein the channel structure extends into the source structure at a greater depth than the slit structure.

19. The manufacturing method of claim 11, wherein the gap-fill pattern is removed when the substrate is removed.

20. The manufacturing method of claim 11, further comprising, after removing the gap-fill pattern, doping the channel structure with impurities.

21. The manufacturing method of claim 11, wherein forming the source structure comprises:
forming a source layer connected to the channel structure;
laser-annealing the source layer; and
planarizing the source layer.

22. The manufacturing method of claim 11, further comprising, before forming the gap-fill pattern, forming a buffer pattern by oxidizing the substrate.

23. The manufacturing method of claim 22, wherein the gap-fill pattern is formed in the buffer pattern.

24. The manufacturing method of claim 22, further comprising, before removing the gap-fill pattern, removing the buffer pattern.

25. A manufacturing method of a semiconductor device, the manufacturing method comprising:
forming a stack over a substrate, the stack including first material layers and second material layers that are alternately stacked;
forming an opening extending into the substrate through the stack;
forming a buffer pattern by oxidizing the substrate through the opening;
forming a gap-fill pattern in the buffer pattern;
forming a channel structure in the opening, the channel structure extending into the buffer pattern;
removing the substrate to expose the buffer pattern;
removing the buffer pattern to expose the gap-fill pattern;
removing the gap-fill pattern; and
forming a source structure connected to the channel structure.

26. The manufacturing method of claim 25, wherein forming the gap-fill pattern comprises:
forming a gap-fill layer in the opening; and
forming the gap-fill pattern by wet-etching the gap-fill layer.

27. The manufacturing method of claim 25, wherein forming the channel structure comprises:
forming a memory layer in the opening, the memory layer extending into the buffer pattern;
forming a channel layer in the memory layer.

28. The manufacturing method of claim 27, further comprising removing the memory layer to expose the channel layer.

29. The manufacturing method of claim 27, wherein the channel layer comprises:
a penetration portion extending through the stack; and
a tip connected to the penetration portion and located in the buffer pattern.
